(19) United States
(12) Patent Application Publication
(10) Pub. No.: US 2026/0285008 A1
(43) Pub. Date: Sep. 24, 2026

(54) THERMOSETTING RESIN COMPOSITION, PREPREG, RESIN FILM, METAL-CLAD LAMINATE, PRINTED WIRING BOARD, ANTENNA DEVICE, ANTENNA MODULE, AND COMMUNICATION DEVICE

(71) Applicant: Resonac Corporation, Minato-ku, Tokyo (JP)

(72) Inventors: Masashi OJI, Minato-ku, Tokyo (JP); Yusuke WATASE, Minato-ku, Tokyo (JP); Yuya HIRAYAMA, Minato-ku, Tokyo (JP); Yoshiki HIDAKA, Minato-ku, Tokyo (JP)

(21) Appl. No.: 19/476,200

(22) PCT Filed: Oct. 18, 2024
(86) PCT No.: PCT/JP2024/037082

§ 371 Date: Oct. 17, 2025

(30) Foreign Application Priority Data
Nov. 29, 2023 (JP) 2023-201908

(51) Int. Cl. B32B 15/08; B32B 41/00; H05K 1/03; H05K 1/18

(52) U.S. Cl. CPC B32B 15/08; B32B 41/00; H05K 1/0373; B32B 2250/02; B32B 2264/1022; B32B 2264/104; B32B 2305/076; B32B 2305/72; B32B 2307/4026; B32B 2379/08; B32B 2457/08; H05K 1/18; H05K 2201/0209; H05K 2201/10098

(57) ABSTRACT

A metal-clad laminate that is capable of being subjected to the substrate visual inspection with an AOI device even for an antenna module may be produced by a thermosetting resin composition. A prepreg, a resin film, a printed wiring board, an antenna device, an antenna module, and a communication device may also be obtained by using the thermosetting resin composition. The thermosetting resin composition is a thermosetting resin composition containing: a thermosetting resin (A); and one or more kinds of a high dielectric constant inorganic filler (B) selected from the group consisting of a titanium-based inorganic filler and a zircon-based inorganic filler, the thermosetting resin composition providing a chart obtained by performing a substrate visual inspection according to the method described in the specification, having a peak derived from a metal foil and a peak derived from a cured product of the thermosetting resin composition that are detected separately.

### TECHNICAL FIELD

The present disclosure relates to a thermosetting resin composition, a prepreg, a resin film, a metal-clad laminate, a printed wiring board, an antenna device, an antenna module, and a communication device.

### BACKGROUND ART

In recent years, mobile terminals, such as smartphones, have become popular, and as a result of technological innovation, such as the Internet of Things (IoT), home appliances and electronic devices having a wireless communication function have increased. This raises a concern that the communication traffic of the wireless network increases and the communication speed and the communication quality are decreased.

In order to solve the problem, the development of the Fifth Generation Mobile Communication System (hereinafter, sometimes referred to as “5G system”) is in progress, and is already being used. In the 5G system, the advanced beam forming and spatial multiplexing are performed using multiple antenna elements, and in addition to signals of frequencies in the 6 GHz band that have been used conventionally, signals of millimeter wave bands with higher frequencies, such as several tens of GHz, are used. Accordingly, it is expected that the communication speed is increased and the communication quality is improved. Hereinafter, a frequency of 10 GHz or higher is referred to as a high frequency.

As described above, in the 5G system, it is necessary for the antenna module to be capable of handling the high-frequency signals, and for this purpose, it is required that the dielectric constant (Dk) and the dielectric dissipation factor (Df) of the laminate in a high-frequency band be low, and in particular, that the dielectric dissipation factor (Df) be low.

Since radio waves of high frequencies have high linearity, signals carried on radio waves of high frequencies tend to be easily blocked by obstacles, such as buildings. Therefore, in order to avoid the blocking, multiple antenna devices are mounted on the antenna module. Since the antenna device can be downsized by increasing the dielectric constant (Dk) of the substrate material, the increase of the dielectric constant (Dk) is effective for mounting multiple antenna devices, and leads to downsizing of the antenna module, which in turn leads to downsizing of the communication device. Therefore, the laminate used in the antenna module that is capable of handling high-frequency signals is required to have a dielectric constant (Dk) of a predetermined level and a low dielectric dissipation factor (Df).

As one of the methods for increasing the dielectric constant (Dk) of the substrate material, a method using a high dielectric constant material is mentioned (for example, refer to PTL 1). The downsized antenna described in PTL 1 is produced by interposing a first dielectric layer of a low dielectric constant material between a second and a third dielectric layer of a high dielectric constant material and laminating the layers.

### CITATION LIST

### Patent Literature

PTL 1: WO 2005/101574

### SUMMARY OF INVENTION

### Technical Problem

The substrate visual inspection with an automated optical inspection (AOI) device is effective as a quality evaluation of substrate materials. The AOI device performs the visual inspection with an optical instrument using reflection of light and the like. The optical instrument can confirm a fine surface state that cannot be confirmed with the naked eye, and therefore the quality evaluation of substrate materials is frequently performed with the AOI device.

However, the investigation by the present inventors has revealed that the metal-clad laminate for an antenna module frequently cannot be subjected to the substrate visual inspection with an AOI device.

In view of the current circumstances, an object of the present disclosure is to provide a metal-clad laminate for an antenna module that is capable of being subjected to the substrate visual inspection with an AOI device, to provide a thermosetting resin composition that is capable of producing the metal-clad laminate, and to provide a prepreg, a resin film, a printed wiring board, an antenna device, an antenna module, and a communication device obtained by using the thermosetting resin composition.

### Solution to Problem

The present inventors have accumulated earnest investigations, and as a result, have found that the object can be achieved by the thermosetting resin composition and the metal-clad laminate of the present disclosure.

The present disclosure includes the following embodiments [1] to [20].
[1] A thermosetting resin composition containing:
a thermosetting resin (A); and
one or more kinds of a high dielectric constant inorganic filler (B) selected from the group consisting of a titanium-based inorganic filler and a zircon-based inorganic filler,
the thermosetting resin composition providing a chart obtained by performing a substrate visual inspection according to the following method, having a peak derived from a metal foil and a peak derived from a cured product of the thermosetting resin composition that are detected separately:
   (substrate visual inspection method)
a metal-clad laminate including a cured product of the thermosetting resin composition and a metal foil laminated on each other is prepared, from which the metal foil is removed by etching while a part of the metal foil is allowed to remain, so as to produce a test piece having a part of a surface of the cured product of the thermosetting resin composition exposed, and the test piece is mounted on and inspected with an automated optical inspection device to provide a graph with a gray level as the abscissa and a pixel as the ordinate, in which a peak derived from the metal foil and a peak derived from the cured product of the thermosetting resin composition are detected.
[2] The thermosetting resin composition according to the item [1], in which the component (A) contains one or more kinds selected from the group consisting of an epoxy resin, a maleimide compound, a modified polyphenylene ether resin, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.
[3] The thermosetting resin composition according to the item [1] or [2], in which the titanium-based inorganic filler is one or more kinds selected from the group consisting of titanium dioxide and a metal titanate.
[4] The thermosetting resin composition according to the item [3], in which the metal titanate is one or more kinds selected from the group consisting of an alkali metal titanate, an alkaline earth metal titanate, and lead titanate.
[5] The thermosetting resin composition according to any one of the items [1] to [4], in which the zircon-based inorganic filler is an alkali metal zirconate.
[6] The thermosetting resin composition according to any one of the items [1] to [5], in which the thermosetting resin composition further contains one or more kinds selected from a dye and a pigment (G).
[7] The thermosetting resin composition according to any one of the items [1] to [6], in which the peak derived from the metal foil appears at a gray level of 230 to 256, and the peak derived from the cured product of the thermosetting resin composition appears at a gray level of 220 or less.
[8] A prepreg containing the thermosetting resin composition according to any one of the items [1] to [7] or a semi-cured product of the thermosetting resin composition.
[9] A resin film containing the thermosetting resin composition according to any one of the items [1] to [7] or a semi-cured product of the thermosetting resin composition.
[10] A metal-clad laminate including a cured product of the thermosetting resin composition according to any one of the items [1] to [7] and a metal foil.
[11] A metal-clad laminate including a cured product of a thermosetting resin composition and a metal foil,
the thermosetting resin composition containing:
a thermosetting resin (A); and
one or more kinds of a high dielectric constant inorganic filler (B) selected from the group consisting of a titanium-based inorganic filler and a zircon-based inorganic filler,
the metal-clad laminate providing a chart obtained by performing a substrate visual inspection according to the following method, having a peak derived from the metal foil and a peak derived from the cured product of the thermosetting resin composition that are detected separately: (substrate visual inspection method)
the metal foil is removed by etching from the metal-clad laminate while a part of the metal foil is allowed to remain, so as to produce a test piece having a part of a surface of the cured product of the thermosetting resin composition exposed, and the test piece is mounted on and inspected with an automated optical inspection device to provide a graph with a gray level as the abscissa and a pixel as the ordinate, in which a peak derived from the metal foil and a peak derived from the cured product of the thermosetting resin composition are detected.
[12] The metal-clad laminate according to the item [11], in which the titanium-based inorganic filler is one or more kinds selected from the group consisting of titanium dioxide and a metal titanate.
[13] The metal-clad laminate according to the item [12], in which the metal titanate is one or more kinds selected from the group consisting of an alkali metal titanate, an alkaline earth metal titanate, and lead titanate.
[14] The metal-clad laminate according to any one of the items to [13], in which the zircon-based inorganic filler is an alkali metal zirconate.
[15] The metal-clad laminate according to any one of the items to [14], in which the metal-clad laminate further includes one or more kinds selected from a dye and a pigment (G).
[16] The metal-clad laminate according to any one of the items to [15], in which the peak derived from the metal foil appears at a gray level of 230 to 256, and the peak derived from the cured product of the thermosetting resin composition appears at a gray level of 220 or less.
[17] A printed wiring board including a cured product of the thermosetting resin composition according to any one of the items [1] to [7].
[18] An antenna device including the metal-clad laminate according to any one of the items [10] to [16].
[19] An antenna module including a feeding circuit and the antenna device according to the item [18].
[20] A communication device including a baseband signal processing circuit and the antenna module according to the item [19].

### Advantageous Effects of Invention

The present disclosure can provide a metal-clad laminate for an antenna module that is capable of being subjected to the substrate visual inspection with an AOI device, can provide a thermosetting resin composition that is capable of producing the metal-clad laminate, and can provide a prepreg, a resin film, a printed wiring board, an antenna device, an antenna module, and a communication device obtained by using the thermosetting resin composition.

### BRIEF DESCRIPTION OF DRAWINGS

FIG. 1 is a schematic top view of one example of a test piece subjected to the substrate visual inspection in the present embodiment.

FIG. 2 is a graph obtained through calibration in the substrate visual inspection in Example 1.

FIG. 3 is a graph obtained through calibration in the substrate visual inspection in Example 2.

FIG. 4 is a graph obtained through calibration in the substrate visual inspection in Comparative Example 1.

FIG. 5 is a graph obtained through calibration in the substrate visual inspection in Comparative Example 2.

### DESCRIPTION OF EMBODIMENTS

In the numerical ranges described in the present disclosure, the upper limit values or the lower limit values of the numerical ranges may be replaced with values shown in Examples. The lower limit values and the upper limit values of the numerical ranges can be optionally combined with the lower limit value or the upper limit value of another numerical range, respectively. In the expression of the numerical range “AA to BB”, the numerical values AA and BB at the ends are included in the numerical range as the lower limit value and the upper limit value, respectively.

In the present disclosure, for example, the description of “10 or more” means 10 and numerical values exceeding 10, which is applied to cases of different numerical values, and for example, the description of “10 or less” means 10 and numerical values less than 10, which is applied to cases of different numerical values.

One kind of each of the components and the materials exemplified in the present disclosure can be used alone, or two or more kinds thereof may be used in combination, unless otherwise indicated. In the present disclosure, in the case where multiple substances corresponding to each of the components exist in the composition, the content of the component in the composition means the total amount of the multiple substances existing in the composition, unless otherwise indicated.

In the present disclosure, the “resin component” refers to all of the solid components constituting the resin composition except for inorganic compounds, such as an inorganic filler described later.

In the present disclosure, the “solid components” refer to components in the resin composition other than a solvent, and a component in a liquid state at 25° C. is also designated as the solid component.

The expression “containing XX” described in the present disclosure definitely shows that XX is simply contained, but also shows that XX in a reacted state is contained.

An embodiment including matters described in the present disclosure optionally combined is also encompassed in the present disclosure and the present embodiment.

### [Thermosetting Resin Composition]

The thermosetting resin composition of the present embodiment is as follows.

The thermosetting resin composition contains:
a thermosetting resin (A) (which may be hereinafter referred to as a component (A)); and
one or more kinds of a high dielectric constant inorganic filler (B) selected from the group consisting of a titanium-based inorganic filler and a zircon-based inorganic filler (which may be hereinafter referred to as a component (B)).

The thermosetting resin composition provides a chart obtained by performing a substrate visual inspection according to the following method, having a peak derived from a metal foil and a peak derived from a cured product of the thermosetting resin composition that are detected separately.

### (Substrate Visual Inspection Method)

A metal-clad laminate including a cured product of the thermosetting resin composition and a metal foil laminated on each other is prepared, from which the metal foil is removed by etching while a part of the metal foil is allowed to remain, so as to produce a test piece having a part of a surface of the cured product of the thermosetting resin composition exposed. The test piece is mounted on and inspected with an automated optical inspection (AOI) device to provide a graph with a gray level as the abscissa and a pixel as the ordinate, in which a peak derived from the metal foil and a peak derived from the cured product of the thermosetting resin composition are detected.

The thermosetting resin composition of the present embodiment contains the component (B), and therefore has a high dielectric constant (Dk), which enables the downsizing of the antenna device. Accordingly, the metal-clad laminate of the present embodiment produced with the thermosetting resin composition is useful for an antenna module. The metal-clad laminate for an antenna module frequently cannot be subjected to the substrate visual inspection with an AOI device, as described above, but the metal-clad laminate of the present embodiment can be visually inspected with an AOI device for the surface of the cured product of the thermosetting resin composition existing under the metal foil. This can be achieved in such a manner that in a chart obtained by performing a substrate visual inspection, the peak derived from the metal foil and the peak derived from the cured product of the thermosetting resin composition are detected separately. In the case where the peak derived from the metal foil and the peak derived from the cured product of the thermosetting resin composition overlap each other, on the other hand, an error occurs in the AOI device, and disables the inspection.

Examples of the usable AOI device include an AOI device “Discovery (registered trade name)” series, available from Orbotech Ltd., while not particularly limited. Examples of “Discovery (registered trade name)” series include Discovery-8000.

In the chart obtained by performing a substrate visual inspection, it is preferred that the peak derived from the metal foil and the peak derived from the cured product of the thermosetting resin composition are completely separated from each other; it is more preferred that the peak derived from the metal foil appears at a gray level of 230 to 256, and the peak derived from the cured product of the thermosetting resin composition appears at a gray level of 220 or less; and it is further preferred that the peak derived from the metal foil appears at a gray level of 235 to 256, and the peak derived from the cured product of the thermosetting resin composition appears at a gray level of 215 or less.

In the description herein, for example, the case where the peak appears at a gray level of 230 to 256 means that the starting point of the peak is 230 or more. A gray level of 256 is the maximum value of the abscissa. For example, furthermore, the case where the peak appears at a gray level of 220 or less means that the end point of the peak is 220 or less. These interpretations are applied to cases with different gray level values.

In the chart obtained by performing a substrate visual inspection, the sizes of the peaks are not particularly limited. The metal-clad laminate for an antenna module generally has a tendency that the peak derived from the cured product of the thermosetting resin composition is larger than the peak derived from the metal foil. For example, the value (number of pixels) of the peak top derived from the cured product of the thermosetting resin composition may become three times or more, or four times or more, the value (number of pixels) of the peak top derived from the metal foil. The value (number of pixels) of the peak top derived from the cured product of the thermosetting resin composition may be generally 20 times or less, or 15 times or less, the value (number of pixels) of the peak top derived from the metal foil.

There is no particular limitation in the method of allowing the peak derived from the metal foil and the peak derived from the cured product of the thermosetting resin composition to be detected separately in the chart obtained by performing a substrate visual inspection. Examples of the effective method therefor include a method of adding one or more kinds selected from a dye and a pigment (G) described later to the thermosetting resin composition. The component (G) contained in the thermosetting resin composition can separate the peak derived from the metal foil and the peak derived from the cured product of the thermosetting resin composition off from each other.

Next, the details of the substrate visual inspection method are described.
(0) A test piece is produced.

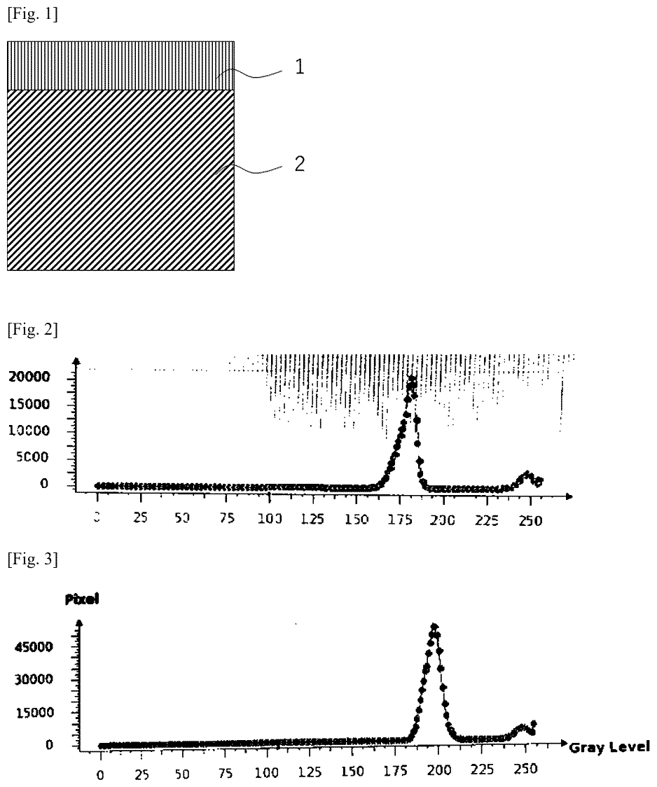

A metal-clad laminate including the cured product of the thermosetting resin composition and the metal foil laminated on each other is prepared. Specifically, the metal-clad laminate can be produced according to the production method of a metal-clad laminate described later. The metal foil of the metal-clad laminate is removed by etching while a part of the metal foil is allowed to remain, so as to produce a test piece having a part of the surface of the cured product of the thermosetting resin composition exposed (see FIG. 1). FIG. 1 shows the state where the surface of the cured product 2 of the thermosetting resin composition having the copper foil 1 remaining on a part thereof.
(1) The test piece is mounted on an automated optical inspection (AOI) device.
(2) Calibration is first performed. The entire test piece is imaged from above the test piece with the camera (i.e., the camera provided inside the AOI device). The image obtained through camera imaging is converted to grayscale. The conversion to grayscale is an operation of converting the color shading and the brightness are converted to black and white shading (256 levels), and can be performed by a known method. The following equation is generally used for the conversion to grayscale.

$$Gray = Red \times 0.3 + Green \times 0.59 + Blue \times 0.11 \qquad [ Math 1 ]$$

in which Gray represents the pixel value of the grayscale image, and Red, Green, and Blue represent the pixel values of the RGB color image.

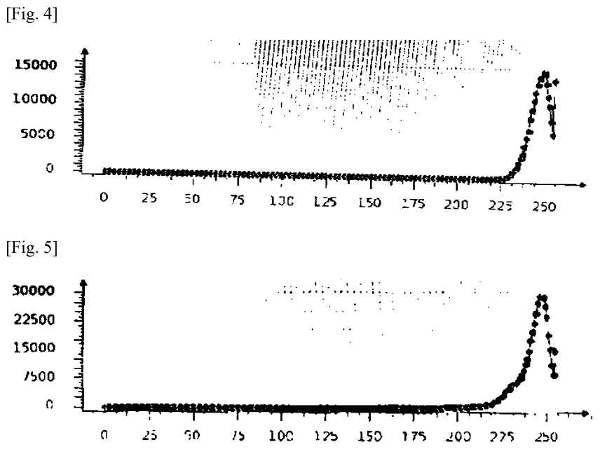

After completing the conversion to grayscale, each one pixel (0.02 to 0.04 mm×0.02 to 0.04 mm), which is the minimum unit of the image, is assigned 256 levels and graphed. For example, in the case where 25,000 pixels corresponding to the 220th level exist, the graph is plotted at the position of a gray level of 220 on the abscissa and 25,000 pixels on the ordinate. Specifically, a graph like those in FIGS. 2 and 3 is obtained. In FIGS. 2 and 3, the small peak on the right end is the peak derived from the metal foil, and the large peak on the left side is the peak derived from the cured product of the thermosetting resin composition. In the present embodiment, the peak derived from the metal foil and the peak derived from the cured product of the thermosetting resin composition can be separated off from each other in this manner, and the operation shown in the section (3) below is enabled thereby.
(3) The threshold value between the peak derived from the metal foil and the peak derived from the cured product of the thermosetting resin composition is then set. The setting of the threshold value can be changed depending on the detection level of defects. For example, the end point (right end) of the peak derived from the cured product of the thermosetting resin composition is designated as the minimum value, whereas the starting point (left end) of the peak derived from the metal foil is designated as the maximum value, from which the difference between the minimum value and the maximum value can be set as the threshold value, and this setting is generally used as the basic setting. In the case where the peak derived from the metal foil and the peak derived from the cured product of the thermosetting resin composition overlap each other in the section (2) above (see FIGS. 4 and 5), the operation of the section (3) cannot be performed, and thereby an error occurs and disables the visual inspection.

The operations up to this section are the calibration.
(4) After the operation of the section (3) above, the visual inspection is performed by imaging the entire test piece from above the test piece with the camera (i.e., the camera provided inside the AOI device). In the imaging, the image size may be ca. 3 mm×ca. 4 mm per one image, while not particularly limited.
(5) The presence of defects is confirmed based on the image obtained in the section (4).

The substrate visual inspection using an AOI device can be performed in the aforementioned manner.

Next, the components contained in the thermosetting resin composition of the present embodiment will be described in detail below.

### (Thermosetting Resin (A))

Examples of the component (A) include an epoxy resin, a maleimide compound, a modified polyphenylene ether resin, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Among these, the component (A) is preferably an epoxy resin, a maleimide compound, and a polyphenylene ether resin, and is more preferably an epoxy resin and a maleimide compound from the standpoint of the low thermal expansion and the heat resistance, more preferably a maleimide compound and a polyphenylene ether resin from the standpoint of the low thermal expansion, the dielectric dissipation factor (Df), and the like.

One kind of the component (A) may be used alone, or two or more kinds thereof may be used in combination.

The epoxy resin is preferably an epoxy resin having two or more epoxy groups in one molecule. Epoxy resins are classified into a glycidyl ether type epoxy resin, a glycidyl amine type epoxy resin, a glycidyl ester type epoxy resin, and the like. Among these, a glycidyl ether type epoxy resin is preferred.

Epoxy resins are also classified into various types of epoxy resins according to the difference in the main skeleton, and each of the above types of epoxy resins is further classified into a bisphenol type epoxy resin, such as a bisphenol A type epoxy resin, a bisphenol F type epoxy resin, and a bisphenol S type epoxy resin; an alicyclic epoxy resin, such as a dicyclopentadiene type epoxy resin; an aliphatic linear epoxy resin; a novolac type epoxy resin, such as a phenol novolac type epoxy resin, a cresol novolac type epoxy resin, a bisphenol A novolac type epoxy resin, a bisphenol F novolac type epoxy resin, a phenol aralkyl novolac type epoxy resin, and a biphenyl aralkyl novolac type epoxy resin; a stilbene type epoxy resin; a naphthalene skeleton-containing epoxy resin, such as a naphthol novolac type epoxy resin and a naphthol aralkyl type epoxy resin; a biphenyl aralkyl type epoxy resin; a xylylene type epoxy resin; and a dihydroanthracene type epoxy resin.

The maleimide compound preferably includes one or more kinds selected from the group consisting of a maleimide compound having one or more (preferably two or more) N-substituted maleimide groups, and a derivative thereof.

Examples of the maleimide compound having one or more N-substituted maleimide groups include, while not particularly limited, an aromatic maleimide compound having one N-substituted maleimide group preferably bonded to an aromatic ring, such as N-phenylmaleimide, N-(2-methylphenyl) maleimide, N-(4-methylphenyl) maleimide, N-(2,6-dimethylphenyl) maleimide, N-(2,6-diethylphenyl) maleimide, N-(2-methoxyphenyl) maleimide, and N-benzylmaleimide; an aromatic bismaleimide compound having two N-substituted maleimide groups preferably bonded to an aromatic ring, such as bis(4-maleimidophenyl) methane, bis(4-maleimidophenyl) ether, bis(4-maleimidophenyl) sulfone, 3,3′-dimethyl-5,5′-diethyl-4,4′-diphenylmethane bismaleimide, 4-methyl-1,3-phenylene bismaleimide, m-phenylene bismaleimide, 2,2-bis[4-(4-maleimidophenoxy)phenyl] propane, and indane ring-containing bismaleimide; an aromatic polymaleimide compound having three or more N-substituted maleimide groups preferably bonded to an aromatic ring, such as polyphenylmethane maleimide and biphenyl aralkyl type maleimide; and an aliphatic maleimide compound, such as N-dodecylmaleimide, N-isopropylmaleimide, N-cyclohexylmaleimide, 1,6-bismaleimido-(2,2,4-trimethyl) hexane, and a pyrophosphoric acid binder type long chain alkyl bismaleimide. Among these, an aromatic bismaleimide compound having two N-substituted maleimide groups preferably bonded to an aromatic ring is more preferred, and 2,2-bis[4-(4-maleimidophenoxy)phenyl] propane is more preferred, from the standpoint of the compatibility with the other resins, the peel strength, the heat resistance, the low thermal expansion, and the mechanical characteristics.

Examples of the derivative of the maleimide compound include an addition reaction product of the maleimide compounds having one or more (preferably two or more)N-substituted maleimide groups and an amine compound, such as a monoamine compound or a diamine compound (hereinafter which may be referred to as a “modified maleimide compound”). Examples of the monoamine compound include a monoamine compound having an acidic substituent, such as o-aminophenol, m-aminophenol, p-aminophenol, o-aminobenzoic acid, m-aminobenzoic acid, p-aminobenzoic acid, o-aminobenzenesulfonic acid, m-aminobenzenesulfonic acid, p-aminobenzenesulfonic acid, 3,5-dihydroxyaniline, and 3,5-dicarboxyaniline. Examples of the diamine compound include 4,4′-diaminodiphenylmethane, 4,4′-diaminodiphenylethane, 4,4′-diaminodiphenylpropane, 2,2-bis[4-(4-aminophenoxy)phenyl] propane, 2,2-bis(4,4′-diaminodiphenyl) propane, 3,3′-dimethyl-4,4′-diaminodiphenylmethane, 3,3′-diethyl-4,4′-diaminodiphenylmethane, 3,3′-dimethyl-4,4′-diaminodiphenylethane, 3,3′-diethyl-4,4′-diaminodiphenylethane, 4,4′-diaminodiphenyl ether, 4,4′-diaminodiphenyl thioether, 3,3′-dihydroxy-4,4′-diaminodiphenylmethane, 2,2′,6,6′-tetramethyl-4,4′-diaminodiphenylmethane, 3,3′-dichloro-4,4′-diaminodiphenylmethane, 3,3′-dibromo-4,4′-diaminodiphenylmethane, 2,2′,6,6′-tetrachloro-4,4′-diaminodiphenylmethane, 2,2′,6,6′-tetrabromo-4,4′-diaminodiphenylmethane, and siloxane diamine. Among these, 2,2-bis[4-(4-aminophenoxy)phenyl] propane, 3,3′-dimethyl-4,4′-diamnodiphenylmethane, and cyclohexanediamine are preferred.

One kind of each of the monoamine compound and the diamine compound may be used alone, or two or more kinds thereof may be used in combination.

The maleimide compound preferably contains an addition reaction product of a maleimide compound having two or more N-substituted maleimide groups and an amine compound, more preferably contains an addition reaction product of a maleimide compound having two or more N-substituted maleimide groups and a diamine compound, and further preferably contains an addition reaction product of a maleimide compound having two or more N-substituted maleimide groups and a diamine compound containing a siloxane diamine.

The weight average molecular weight of the maleimide compound is not particularly limited, and is preferably 400 to 10,000, more preferably 1,000 to 5,000, further preferably 1,500 to 4,000, and particularly preferably 2,000 to 3,000, from the standpoint of the handleability and the moldability. In the present disclosure, the weight average molecular weight (Mw) means a value that is measured through gel permeation chromatography (GPC) in terms of polystyrene conversion.

The modified polyphenylene ether resin is preferably a polyphenylene ether resin having an ethylenically unsaturated bond-containing group at an end, and more preferably a polyphenylene ether resin having an ethylenically unsaturated bond-containing group at both ends. The “ethylenically unsaturated bond-containing group” herein means a substituent containing a carbon-carbon double bond capable of performing addition reaction, and does not include a double bond of an aromatic ring. Examples of the ethylenically unsaturated bond-containing group include an unsaturated aliphatic hydrocarbon group, such as a vinyl group, an allyl group, a 1-methylallyl group, an isopropenyl group, a 2-butenyl group, a 3-butenyl group, and a styryl group; and a group containing a hetero atom and an ethylenically unsaturated bond, such as a maleimide group and a (meth)acryloyl group. The ethylenically unsaturated bond-containing group is preferably a group containing a hetero atom and an ethylenically unsaturated bond, more preferably a (meth)acryloyl group, and further preferably a methacryloyl group.

In the present disclosure, the “(meth)acryloyl group” means an acryloyl group or a methacryloyl group.

The weight average molecular weight of the modified polyphenylene ether resin is not particularly limited, and is preferably 400 to 10,000, more preferably 500 to 5,000, further preferably 500 to 3,500, and particularly preferably 1,000 to 3,000, from the standpoint of the handleability and the moldability.

### (Content of Component (A))

The content of (A) the thermosetting resin in the thermosetting resin composition of the present embodiment is not particularly limited, and is preferably 5 to 95 parts by mass, more preferably 10 to 80 parts by mass, further preferably 10 to 60 parts by mass, and particularly preferably 15 to 40 parts by mass, per 100 parts by mass of the solid components in the thermosetting resin composition, from the standpoint of the dielectric dissipation factor (Df), the heat resistance, and the moldability.

(One or More Kind of High Dielectric Constant Inorganic Filler (B) Selected from Group Consisting of Titanium-Based Inorganic Filler and Zircon-Based Inorganic Filler)

The titanium-based inorganic filler is preferably one or more kinds selected from the group consisting of titanium dioxide and a metal titanate from the standpoint of the dielectric constant (Dk). Examples of the metal titanate include an alkali metal titanate, such as potassium titanate; an alkaline earth metal titanate, such as barium titanate, calcium titanate, and strontium titanate; and lead titanate, from the standpoint of the dielectric constant (Dk). The metal titanate is preferably one or more kinds selected from the above examples, and is more preferably an alkaline earth metal titanate, and further preferably calcium titanate or strontium titanate, from the standpoint of the dielectric constant (Dk).

The zircon-based inorganic filler is preferably an alkali metal zirconate from the standpoint of the dielectric constant (Dk). The alkali metal zirconate is preferably one or more kinds selected from the group consisting of calcium zirconate and strontium zirconate from the standpoint of the dielectric constant (Dk).

The component (B) is preferably a titanium-based inorganic filler, and more preferred examples thereof are as described above, from the standpoint of the dielectric dissipation factor (Df) and the specific gravity.

The average particle diameter of the component (B) is not particularly limited, is preferably 0.1 μm or more, and more preferably 0.4 μm or more, and is further preferably 1.0 μm or more, and particularly preferably 1.5 μm or more, from the standpoint of the heat resistance. The upper limit of the average particle diameter of the component (B) is preferably 4.5 μm or less, more preferably 4.0 μm or less, further preferably 3.5 μm or less, particularly preferably 3.0 μm or less, and most preferably 2.5 μm or less, from the standpoint of excluding coarse particles possibly causing insulation failure.

Accordingly, the average particle diameter of the component (B) is preferably 0.1 to 4.5 μm, and the upper limit value and the lower limit value of the numerical range can be changed based on the above description.

In the present disclosure, the average particle diameter refers to an average primary particle diameter. In the present disclosure, the average particle diameter is a value of d50 (median diameter of volume distribution) obtained by analysis of the particle size distribution using a particle diameter distribution analyzer. The details of the specific method and conditions for analyzing the particle size distribution may be in accordance with the description in the section of Examples.

The shape of the component (B) is not particularly limited, and may be an irregular shape since an industrially available high dielectric constant inorganic filler generally has an irregular shape in many cases, or may be another shape, such as a spherical shape.

### (Content of Component (B))

The content of the component (B) in the thermosetting resin composition of the present embodiment is not particularly limited, is preferably 1 to 60% by volume, and more preferably 2 to 30% by volume, may be 3 to 20% by volume, may be 7 to 30% by volume, and may be 12 to 25% by volume, based on the solid components in the thermosetting resin composition, from the standpoint of the dielectric constant (Dk). The content of the component (B) described in terms of part by mass is preferably 5 to 95 parts by mass, more preferably 15 to 90 parts by mass, further preferably 20 to 70 parts by mass, particularly preferably 20 to 55 parts by mass, and most preferably 25 to 50 parts by mass, per 100 parts by mass of the solid components in the thermosetting resin composition.

In the case where the content of the component (B) in the thermosetting resin composition of the present embodiment is the lower limit value or more, the dielectric constant (Dk) tends to be sufficiently increased, and in the case where the content thereof is the upper limit value or less, the excessive increase in the dielectric dissipation factor (Df) tends to be suppressed.

### (Elastomer (C))

The thermosetting resin composition of the present embodiment preferably further contains an elastomer (C) while not particularly limited.

Examples of the elastomer (C) include a styrene elastomer, an olefin elastomer, a urethane elastomer, a polyester elastomer, a polyamide elastomer, an acrylic elastomer, and a silicone elastomer. The elastomers each include a hard segment component and a soft segment component, in which the hard segment component generally contributes to the heat resistance and the strength, and the soft segment component generally contributes to the flexibility and the toughness.

One kind of the elastomer (C) may be used alone, or two or more kinds thereof may be used in combination.

The elastomer (C) is preferably a styrene-based elastomer, and more preferably a styrene-based thermoplastic elastomer, from the standpoint of the high frequency characteristics. It suffices that the styrene-based elastomer has a structural unit derived from a styrene-based compound, in which one or more kinds selected from the group consisting of a hydrogenated product of a styrene-butadiene-styrene block copolymer (SEBS and SBBS), a hydrogenated product of a styrene-isoprene-styrene block copolymer (SEPS), and a styrene-maleic anhydride copolymer (SMA) is preferred, one or more kinds selected from the group consisting of a hydrogenated product of a styrene-butadiene-styrene block copolymer (SEBS) and a hydrogenated product of a styrene-isoprene-styrene block copolymer (SEPS) is more preferred, and a hydrogenated product of a styrene-butadiene-styrene block copolymer (SEBS) is further preferred, from the standpoint of the high frequency characteristics, the adhesiveness to a conductor, the heat resistance, and the low thermal expansion.

The styrene-based elastomer (herein, except for SMA above) may be modified with an acid anhydride, such as maleic anhydride, and examples thereof include SEBS modified with an acid anhydride, such as maleic anhydride, and SEPS modified with an acid anhydride, such as maleic anhydride. The acid number of the acid-modified styrene-based elastomer (herein, except for SMA above) is not particularly limited, and is preferably 2 to 20 mgCH₃ONa/g, more preferably 5 to 15 mgCH₃ONa/g, and further preferably 7 to 13 mgCH₃ONa/g.

In the styrene-based elastomer, the content rate of the structural unit derived from styrene (hereinafter, which may be referred to as a “styrene content rate”) is not particularly limited, and is preferably 5 to 80% by mass, more preferably 10 to 75% by mass, further preferably 15 to 60% by mass, and particularly preferably 20 to 45% by mass, from the standpoint of the high frequency characteristics, the adhesiveness to a conductor, the heat resistance, and the low thermal expansion.

The weight average molecular weight (Mw) of the styrene-based elastomer is not particularly limited, and is preferably 12,000 to 1,000,000, more preferably 30,000 to 500,000, further preferably 50,000 to 120,000, and particularly preferably 70,000 to 100,000.

The melt flow rate (MFR) of the styrene-based elastomer is not particularly limited, and is preferably 0.1 to 20 g/10 min, more preferably 1 to 15 g/10 min, further preferably 2 to 10 g/10 min, and particularly preferably 3 to 7 g/10 min, under the measurement condition of 230° C. and a load of 2.16 kgf (21.2 N).

### (Content of Component (C))

In the case where the thermosetting resin composition of the present embodiment contains the elastomer (C), the content thereof is not particularly limited, and is preferably 1 to 20 parts by mass, more preferably 2 to 15 parts by mass, and further preferably 3 to 10 parts by mass, per 100 parts by mass of the solid components in the thermosetting resin composition. In the case where the content of the elastomer (C) is the lower limit value or more, the further excellent high frequency characteristics tend to be obtained, and in the case where the content thereof is the upper limit value or less, good properties tend to be obtained for the heat resistance, the moldability, the processability, and the flame retardancy.

The thermosetting resin composition of the present embodiment may further contain an additional component. The additional component is not particularly limited, and the resin composition preferably contains one or more kinds selected from the group consisting of an inorganic filler (D) (except for the component (B)), a coupling agent, a curing accelerator (E), a flame retardant (F), one or more kinds selected from a dye and a pigment (G), an antioxidant, a flame retardant auxiliary, an adhesiveness improver, a heat stabilizer, an antistatic agent, an ultraviolet ray absorber, and a lubricant.

### (Inorganic Filler (D))

The thermosetting resin composition of the present embodiment preferably further contains an inorganic filler (D) while not particularly limited.

The inorganic filler (D) contained tends to allow the thermosetting resin composition of the present embodiment to have further excellent properties for the low thermal expansion, the high elastic modulus, the heat resistance, and the flame retardancy. However, the inorganic filler (D) does not encompass the component (B).

One kind of the inorganic filler (D) may be used alone, or two or more kinds thereof may be used in combination.

Examples of the inorganic filler (D) include silica, alumina, mica, beryllia, aluminum carbonate, magnesium hydroxide, aluminum hydroxide, aluminum silicate, calcium carbonate, calcium silicate, magnesium silicate, silicon nitride, boron nitride, clay, such as calcined clay, a molybdic acid compound, such as zinc molybdate, talc, aluminum borate, and silicon carbide. Among these, silica, alumina, mica, and talc are preferred, silica and alumina are more preferred, and silica is further preferred, from the standpoint of the low thermal expansion, the elastic modulus, the heat resistance, and the flame retardancy. Examples of the silica include crushed silica, fumed silica, and fused silica. Among these, fused silica is preferred, and fused spherical silica is more preferred.

The average particle diameter of the inorganic filler (D) is not particularly limited, and is preferably 0.01 to 20 μm, more preferably 0.1 to 10 μm, further preferably 0.2 to 3 μm, and particularly preferably 0.3 to 1.0 μm.

### (Content of Component (D))

In the case where the thermosetting resin composition of the present embodiment contains the inorganic filler (D), the content thereof is not particularly limited, and the content thereof is preferably 3 to 70% by volume, more preferably 5 to 65% by volume, further preferably 5 to 60% by volume, furthermore preferably 10 to 50% by volume, particularly preferably 10 to 40% by volume, and most preferably 10 to 30% by volume, based on the solid components in the thermosetting resin composition, from the standpoint of the thermal expansion coefficient, the elastic modulus, the heat resistance, and the flame retardancy.

The content of the component (D) in terms of part by mass is preferably 1 to 60 parts by mass, more preferably 5 to 50 parts by mass, further preferably 10 to 45 parts by mass, particularly preferably 15 to 45 parts by mass, and most preferably 20 to 40 parts by mass, per 100 parts by mass of the solid components in the thermosetting resin composition.

In the case where the inorganic filler is used, a coupling agent may be used in combination depending on necessity for the purpose of improving the dispersibility of the inorganic filler and the adhesiveness to the organic components in the resin composition. Examples of the coupling agent include a silane coupling agent and a titanate coupling agent. One kind of the coupling agent may be used alone, or two or more kinds thereof may be used in combination.

In the case where the coupling agent is used, while the treatment method therewith may be the so-called integral blend method of blending the inorganic filler in the resin composition and then adding the coupling agent thereto, it is preferred to use a method of using the inorganic filler having been surface-treated with the coupling agent in advance by a dry or wet method. This method adopted can allow the inorganic filler to exhibit the characteristics thereof more effectively.

The inorganic filler may also be used in the form of a slurry containing the inorganic filler having been dispersed in an organic solvent in advance, depending on necessity.

### (Curing Accelerator (E))

The thermosetting resin composition of the present embodiment preferably further contains a curing accelerator (E) while not particularly limited.

Examples of the curing accelerator (E) include an amine-based curing accelerator, an imidazole-based curing accelerator, a phosphorus-based curing accelerator, an organometallic salt, an acidic catalyst, and an organic peroxide. In the present embodiment, an imidazole-based curing accelerator is not classified into an amine-based curing accelerator. One kind of the curing accelerator may be used alone, or two or more kinds thereof may be used in combination. The curing accelerator is preferably an amine-based curing accelerator, an imidazole-based curing accelerator, or a phosphorus-based curing accelerator.

Examples of the amine-based curing accelerator include an amine compound having a primary to tertiary amino group, such as triethylamine, 4-aminopyridine, tributylamine, and dicyandiamide; and a quaternary ammonium compound.

Examples of the imidazole-based curing accelerator include an imidazole compound, such as methylimidazole, phenylimidazole, 2-undecylimidazole, and isocyanate-masked imidazole (for example, an addition reaction product of a hexamethylene diisocyanate resin and 2-ethyl-4-methylimidazole).

Examples of the phosphorus-based curing accelerator include a tertiary phosphine, such as triphenylphosphine; and a quaternary phosphonium compound, such as a tri-n-butylphosphine addition reaction product of p-benzoquinone.

### (Content of Curing Accelerator (E))

In the case where the thermosetting resin composition of the present embodiment contains the curing accelerator (E), the content thereof is not particularly limited, and is preferably 0.01 to 3 parts by mass, more preferably 0.05 to 2.5 parts by mass, further preferably 0.1 to 2.5 parts by mass, and particularly preferably 0.5 to 2.3 parts by mass, per 100 parts by mass of the resin components in the thermosetting resin composition. In the case where the content of the curing accelerator (E) is in the range, better properties tend to be obtained for the dielectric dissipation factor (Df), the heat resistance, the storage stability, and the moldability.

### (Flame Retardant (F))

The thermosetting resin composition of the present embodiment preferably further contains a flame retardant (F) while not particularly limited.

Examples of the flame retardant (F) include an inorganic phosphorus-based flame retardant, an organic phosphorus-based flame retardant, and a metal hydrate, such as aluminum hydroxide hydrate and magnesium hydroxide hydrate. Although a metal hydroxide may also correspond to the inorganic filler, a metal hydroxide that is capable of imparting flame retardancy is classified into a flame retardant. Among these, the flame retardant (F) is preferably an organic phosphorus-based flame retardant.

Examples of the organic phosphorus-based flame retardant include an aromatic phosphate ester, a phosphonate diester, and a phosphinate ester; a phosphinic acid metal salt, an organic nitrogen-containing phosphorus compound, and a cyclic organophosphorus compound. Examples of the “metal salt” herein include a lithium salt, a sodium salt, a potassium salt, a calcium salt, a magnesium salt, an aluminum salt, a titanium salt, and a zinc salt. Among these, the organic phosphorus-based flame retardant is preferably an aromatic phosphate ester.

### (Content of Component (F))

In the case where the thermosetting resin composition of the present embodiment contains the flame retardant (F), the content thereof is not particularly limited, and is preferably 0.1 to 30 parts by mass, may be 1 to 25 parts by mass, may be 3 to 20 parts by mass, and may be 5 to 15 parts by mass, per 100 parts by mass of the solid components in the thermosetting resin composition. In the case where the content of the flame retardant (F) is the lower limit value or more, the better flame retardancy tends to be obtained. In the case where the content thereof is the upper limit value or less, better properties for the moldability and the peel strength, and the further excellent heat resistance tend to be obtained.

(One or More Kind Selected from Dye and Pigment (G))

The thermosetting resin composition of the present embodiment preferably further contains one or more kinds selected from a dye and a pigment (G). The component (G) contained in the thermosetting resin composition of the present embodiment can easily separate the peak derived from the metal foil and the peak derived from the cured product of the thermosetting resin composition off from each other. It is considered that this may be caused by the effect of the component (G) suppressing the light reflection of the cured product of the thermosetting resin composition.

The component (G) used is preferably both a dye and a pigment from the standpoint of easily separating the peak derived from the metal foil and the peak derived from the cured product of the thermosetting resin composition off from each other, while not particularly limited.

The dye used may be a known dye. Examples of the dye include a coumarin-based dye, an anthraquinone-based dye, a pyrazolone-based dye, a perinone-based dye, a methine-based dye, and a quinophthalone-based dye. The dye is preferably a yellow dye, and more preferably a pyrazolone-based dye, from the standpoint of easily separating the peak derived from the metal foil and the peak derived from the cured product of the thermosetting resin composition off from each other, while not particularly limited.

The pigment used may be, for example, a known pigment. Examples of the pigment include an inorganic pigment and an organic pigment.

Examples of the inorganic pigment include a metal compound, such as a metal oxide and a metal complex salt; a natural mineral pigment, such as graphite; and a synthetic inorganic pigment, such as iron blue, zinc flower, and cobalt blue. Examples of the metal oxide include oxides and composite oxides of iron, cobalt, aluminum, cadmium, lead, copper, titanium, magnesium, chromium, zinc, and antimony. Examples of the metal complex salt include metal complex salts containing a metal ion, such as Cr, Cu, Ni, and Co.

Examples of the organic pigment include a yellow pigment, such as a coumarin-based pigment and various kinds of C.I. Pigment Yellow; an orange pigment, such as various kinds of C.I. Pigment Orange; a red pigment, such as various kinds of C.I. Pigment Red; a blue-violet pigment, such as various kinds of C.I. Pigment Violet; a blue pigment, such as various kinds of C.I. Pigment Blue; and a black pigment, such as various kinds of C.I. Pigment Black. The term C.I. herein means Color Index. The organic pigment is preferably a yellow pigment, and more preferably a coumarin-based pigment, from the standpoint of easily separating the peak derived from the metal foil and the peak derived from the cured product of the thermosetting resin composition off from each other, while not particularly limited.

### (Content of Component (G))

In the case where the thermosetting resin composition of the present embodiment contains the component (G), the content thereof is not particularly limited, and is preferably 0.01 to 10 parts by mass, may be 0.1 to 5 parts by mass, may be 0.1 to 3 parts by mass, and may be 0.3 to 2 parts by mass, per 100 parts by mass of the solid components in the thermosetting resin composition. In the case where the content of the component (G) is the lower limit value or more, the peak derived from the metal foil and the peak derived from the cured product of the thermosetting resin composition tend to be easily separated off from each other. In the case where the content thereof is the upper limit value or less, the heat resistance and the insulation reliability tend to be retained favorably.

(Content of Component Other than Aforementioned Components)

In the case where the thermosetting resin composition of the present embodiment contains a component other than the aforementioned components (for example, a flame retardant aid, an adhesiveness improver, a heat stabilizer, an antistatic agent, an ultraviolet ray absorber, a lubricant, and other components), the content of each of the components is not particularly limited, may be, for example, 0.01 parts by mass or more, may be 10 parts by mass or less, may be 5 parts by mass or less, and may be 1 part by mass or less, per 100 parts by mass of the resin components of the thermosetting resin composition, and the components may not be contained.

In the thermosetting resin composition of the present embodiment, the total amount of the components (A) to (G) may be 50 to 100% by mass, may be 70 to 100% by mass, may be 80 to 100% by mass, may be 90 to 100% by mass, and may be 95 to 100% by mass, based on the solid components of the thermosetting resin composition.

### (Organic Solvent)

The thermosetting resin composition of the present embodiment may be a so-called “varnish” containing an organic solvent from the standpoint of the handleability and the standpoint of facilitating the production of a prepreg described later.

Examples of the organic solvent include, while not particularly limited, an alcohol-based solvent, such as ethanol, propanol, butanol, methyl cellosolve, butyl cellosolve, and propylene glycol monomethyl ether; a ketone-based solvent, such as acetone, methyl ethyl ketone, methyl isobutyl ketone, and cyclohexanone; an ether-based solvent, such as tetrahydrofuran; an aromatic solvent, such as toluene, xylene, and mesitylene; a nitrogen atom-containing solvent, such as dimethylformamide, dimethylacetamide, and N-methylpyrrolidone; a sulfur atom-containing solvent, such as dimethyl sulfoxide; and an ester-based solvent, such as γ-butyrolactone. A ketone-based solvent is preferred, and methyl isobutyl ketone is more preferred, from the standpoint of the solubility. One kind of the organic solvent may be used alone, or two or more kinds may be used in combination.

In the case where the thermosetting resin composition of the present embodiment is used in the form of a varnish, the concentration of the solid components is preferably 30 to 90% by mass, more preferably 40 to 80% by mass, and further preferably 55 to 70% by mass. In the case where the concentration of the solid components in the thermosetting resin composition is in the range, the handleability of the thermosetting resin composition is improved, the impregnation into a base material and the appearance of a prepreg produced are improved, and the coatability in forming a resin film is also improved.

The thermosetting resin composition of the present embodiment can be produced by mixing the components (A) and (B) and the components that can be used depending on necessity by a known method. At this time, the components may be dissolved or dispersed in the organic solvent under stirring. The conditions, such as the mixing order, the temperature, and the time, are not particularly limited, and can be optionally determined.

The thermosetting resin composition of the present embodiment can exhibit a high dielectric constant (Dk) and a low dielectric dissipation factor (Df), and therefore is useful for an antenna module, in particular, for a downsized antenna module applicable to the fifth generation mobile communication (5G) system.

### [Prepreg]

The prepreg of the present embodiment is a prepreg containing the thermosetting resin composition of the present embodiment or a semi-cured product of the thermosetting resin composition.

The prepreg of the present embodiment contains, for example, the thermosetting resin composition of the present embodiment or a semi-cured product of the thermosetting resin composition and a sheet-shaped fiber base material. The prepreg is formed using the thermosetting resin composition of the present embodiment and the sheet-shaped fiber base material, and can be obtained, for example, by impregnating or coating the sheet-shaped fiber base material with the thermosetting resin composition of the present embodiment, drying, and semi-curing (B-staging) depending on necessity. More specifically, for example, the prepreg of the present embodiment can be produced through drying with heat usually at a temperature of 80 to 200° C. for 1 to 30 minutes in a drying furnace, followed by semi-curing (B-staging). The B-staging in the present disclosure means to bring into a B-stage defined in JIS K6900 (1994).

The amount of the thermosetting resin composition used can be appropriately determined for the purpose of allowing the concentration of solid components derived from the thermosetting resin composition in the prepreg after drying to be 30 to 90% by mass. In the case where the concentration of solid components is in the range, the better moldability tends to be obtained in forming a laminate.

The sheet-shaped fiber base material used in the prepreg may be a known one used for various laminates for electrical insulating materials. Examples of the material of the sheet-shaped fiber base material include inorganic fibers, such as E glass, D glass, S glass, and Q glass; organic fibers, such as polyimide, polyester, and tetrafluoroethylene; and a mixture thereof. The sheet-shaped fiber base material may have a form, for example, of a woven fabric, a nonwoven fabric, a roving, a chopped strand mat, or a surfacing mat.

The thickness of the prepreg is not particularly limited, and may be 10 to 170 μm, may be 10 to 120 μm, or may be 10 to 70 μm.

The prepreg of the present embodiment can exhibit a high dielectric constant (Dk) and a low dielectric dissipation factor (Df), and therefore is useful for an antenna module, in particular, for a downsized antenna module applicable to the 5G system.

### [Resin Film]

The resin film of the present embodiment is a resin film containing the thermosetting resin composition of the present embodiment or a semi-cured product of the thermosetting resin composition.

The resin film of the present embodiment can be produced, for example, by applying a thermosetting resin composition containing an organic solvent, i.e., a varnish, to a support, followed by drying with heat, and semi-curing (B-staging) depending on necessity.

Examples of the support include a plastic film, a metal foil, and a release paper.

The drying temperature and the drying time may be appropriately determined according to the amount of the organic solvent used, the boiling point of the organic solvent used, and the like, and the resin film can be favorably formed by drying at 50 to 200° C. for approximately 1 to 10 minutes.

The resin film of the present embodiment can exhibit a high dielectric constant (Dk) and a low dielectric dissipation factor (Df), and therefore is useful for an antenna module, in particular, for a downsized antenna module applicable to the 5G system.

### [Metal-Clad Laminate]

The metal-clad laminate of the present embodiment is a metal-clad laminate including a cured product of the thermosetting resin composition of the present embodiment and a metal foil.

The metal-clad laminate of the present embodiment can be produced, for example, by disposing a metal foil on one surface or both surfaces of a prepreg obtained by stacking two or more sheets of the prepreg of the present embodiment, or disposing a metal foil on one surface or both surfaces of a prepreg obtained by stacking two or more sheets in total of the prepregs of the present embodiment and a prepreg other than that of the present embodiment, followed by subjecting to heat press molding. In the metal-clad laminate obtained by the production method, the prepreg of the present embodiment has been C-staged. In the present disclosure, the C-staging is to bring into a C-stage as defined in JIS K6900 (1994).

The metal-clad laminate of another aspect of the present embodiment can be produced, for example, by disposing a metal foil on one surface or both surfaces of one sheet of the resin film of the present embodiment, or disposing a metal foil on one surface or both surfaces of a laminate obtained by stacking two or more sheets of the resin films of the present embodiment, followed by subjecting to heat press molding, so as to produce the laminate. In the laminate obtained by the production method, the resin film of the present embodiment has been C-staged.

The metal of the metal foil is not particularly limited, and may be copper, gold, silver, nickel, platinum, molybdenum, ruthenium, aluminum, tungsten, iron, titanium, chromium, or an alloy containing one or more of kinds of the metallic elements, and is preferably copper or aluminum, and more preferably copper, from the standpoint of the conductivity.

The conditions of the heat press molding are not particularly limited, and the heat press molding can be carried out, for example, at a temperature in the range of 100 to 300° C., a pressure in the range of 0.2 to 10 MPa, and for a time period in the range of 0.1 to 5 hours. The heat press molding can be carried out by a method of maintaining a vacuum state for 0.5 to 5 hours using a vacuum press or the like.

The metal-clad laminate of the present embodiment can also be paraphrased as a metal-clad laminate including a cured product of a thermosetting resin composition and a metal foil,
the thermosetting resin composition containing:
a thermosetting resin (A); and
one or more kinds of a high dielectric constant inorganic filler (B) selected from the group consisting of a titanium-based inorganic filler and a zircon-based inorganic filler,
the metal-clad laminate providing a chart obtained by performing a substrate visual inspection according to the following method, having a peak derived from the metal foil and a peak derived from the cured product of the thermosetting resin composition that are detected separately. The details of the thermosetting resin composition and the details of the substrate visual inspection method have been described above.

### (Substrate Visual Inspection Method)

The metal foil is removed by etching from the metal-clad laminate while a part of the metal foil is allowed to remain, so as to produce a test piece having a part of a surface of the cured product of the thermosetting resin composition exposed. The test piece is mounted on and inspected with an automated optical inspection device to provide a graph with a gray level as the abscissa and a pixel as the ordinate, in which a peak derived from the metal foil and a peak derived from the cured product of the thermosetting resin composition are detected.

The metal-clad laminate of the present embodiment can exhibit a high dielectric constant (Dk) and a low dielectric dissipation factor (Df), and therefore is useful for an antenna module, in particular, for a downsized antenna module applicable to the 5G system.

In consideration of use for an antenna module, the metal-clad laminate of the present embodiment preferably has a conductor pattern, such as a feeding conductor pattern, a grounding conductor pattern, and a short-circuiting conductor. The short-circuiting conductor is a conductor that short-circuits the feeding conductor pattern and the grounding conductor pattern, and is provided in a via hole portion described later.

The conductor pattern is preferably formed of a metal containing copper, aluminum, gold, silver, and an alloy thereof as a major component.

The metal-clad laminate of the present embodiment preferably has a via hole. The via hole enables the formation of the short-circuiting conductor, and enables the conduction of the feeding conductor pattern and the grounding conductor pattern.

The method for forming the via hole is not particularly limited, and a method using laser, plasma, a combination thereof, or the like, can be used. Examples of the laser used include a carbon dioxide gas laser, a YAG laser, a UV laser, and an excimer laser.

After the formation of the via hole, a desmearing treatment may be performed with an oxidizing agent. The oxidizing agent is preferably a permanganate, such as potassium permanganate or sodium permanganate; a dichromate; ozone; hydrogen peroxide-sulfuric acid; or nitric acid, more preferably a permanganate, and further preferably a sodium hydroxide aqueous solution of a permanganate, which is a so-called alkaline permanganate aqueous solution.

The metal-clad laminate of the present embodiment may include a short-circuiting conductor formed in the via hole after the formation of the via hole. The conductor used herein is preferably formed of the same metal as the metal that forms the conductor patterns.

### [Printed Wiring Board]

The printed wiring board of the present embodiment is a printed wiring board including one or more kinds selected from the group consisting of a cured product of the thermosetting resin composition of the present embodiment and a cured product of the prepreg of the present embodiment. The printed wiring board of the present embodiment can also be paraphrased as being a printed wiring board that has one or more kinds selected from the group consisting of a cured product of the thermosetting resin composition of the present embodiment, a cured product of the prepreg of the present embodiment, and the metal-clad laminate of the present embodiment.

The printed wiring board of the present embodiment can be produced, for example, by using one or more kinds selected from the group consisting of the prepreg of the present embodiment, the resin film of the present embodiment, and the metal-clad laminate of the present embodiment to perform a circuit formation process through drilling, metal plating, etching of a metal foil, or the like by a known method. A multilayer printed wiring board can also be produced by further performing a multilayer adhesion process depending on necessity. In the printed wiring board of the present embodiment, the prepreg of the present embodiment or the resin film of the present embodiment is C-staged to be a cured product.

### [Antenna Device]

The present disclosure also provides an antenna device including the metal-clad laminate or the printed wiring board of the present embodiment. The antenna device may be provided with one metal-clad laminate or printed wiring board, or may be provided with multiple metal-clad laminates or printed wiring boards. The arrangement of the multiple antenna elements installed is not particularly limited, and for example, it is preferred to arrange in a two-dimensional array. The configuration of the antenna device is not particularly limited, and, for example, JP 6777273 B can be referred to.

### [Antenna Module]

The present disclosure also provides an antenna module including a feeding circuit and the antenna device of the present embodiment. The feeding circuit is not particularly limited, and a radio frequency integrated circuit (RFIC) or the like can be used. RFIC includes a switch, a power amplifier, a low-noise amplifier, phase shifter, a signal synthesizer/demultiplexer, a mixer, an amplifier circuit, and the like.

A high-frequency signal supplied from the RFIC is transmitted via the short-circuiting conductor formed in the via of the metal-clad laminate for an antenna module to the feeding point of the feeding conductor.

The configuration of the antenna module is not particularly limited, and, for example, JP 6777273 B can be referred to.

### [Communication Device]

The present disclosure also provides a communication device including a baseband signal processing circuit and the antenna module of the present embodiment.

The communication device of the present embodiment can upconvert a signal transmitted from the baseband signal processing circuit to the antenna module to a high-frequency signal, which is radiated from the antenna device, and also can downconvert a high-frequency signal received by the antenna device, and process the signal in the baseband signal processing circuit.

While the preferred embodiments have been described above, the embodiments are examples for describing the present disclosure, and the scope of the present disclosure is not limited only to the embodiments. The present disclosure may include various aspects different from the embodiments without departing from the gist thereof.

### EXAMPLES

The present embodiment will be specifically described with reference to examples below. However, the present embodiment is not limited to the examples.

In each of the examples, the weight average molecular weight (Mw) was measured by the following method.

(Method for measuring Weight Average Molecular Weight (Mw))

The weight average molecular weight was determined by gel permeation chromatography (GPC) in terms of conversion based on a calibration curve using standard polystyrenes. The calibration curve was approximated by a cubic equation using standard polystyrenes: TSK standard POLYSTYRENE (Type; A-2500, A-5000, F-1, F-2, F-4, F-10, F-20, F-40) (available from Tosoh Corporation, trade name). The measurement conditions of GPC are shown below.

### Apparatus:

Pump: L-6200 type (available from Hitachi High-Tech Corporation)
Detector: L-3300 type RI (available from Hitachi High-Tech Corporation)
Column oven: L-655A-52 (available from Hitachi High-Tech Corporation)
Column: guard column; TSK Guardcolumn HHR-L+column; TSKgel G4000HHR+TSKgel G2000HHR (all available from Tosoh Corporation, trade names)
Column size: 6.0×40 mm (guard column), 7.8× 300 mm (column)
Eluent: tetrahydrofuran
Sample concentration: 30 mg/5 ml
Injection volume: 20 μL
Flow rate: 1.00 mL/min
Measurement temperature: 40° C.

The average particle sizes of the component (B) and the component (D) used in each Example were measured by the following method.

### (Method for Measuring Average Particle Diameter)

The particle size distribution was measured with a particle diameter distribution analyzer “Microtrac MT3300EXII” (available from MicrotracBEL Corp.) to determine the average particle diameter (d50). Water (containing 0.1% by mass of sodium hexametaphosphate) was used as a measurement solvent, and the measurement was performed in a transmission mode for a measurement time of 30 seconds.

### Production Example 1: Production of Modified Maleimide Compound

In a heatable and coolable reaction vessel having a capacity of 5 L equipped with a thermometer, a stirrer, and a water volume meter with a reflux condenser, 100 parts by mass of 2,2-bis[4-(4-meleimidephenoxy)phenyl] propane, 5.6 parts by mass of a siloxane compound having amino groups at both ends (functional group equivalent: 750 g/mol), 7.9 parts by mass of 3,3′-diethyl-4,4′-diaminodiphenylmethane, and 171 parts by mass of propylene glycol monomethyl ether were placed, and reacted for 2 hours under refluxing. The reaction mixture was concentrated at the refluxing temperature over 3 hours, thereby producing a modified maleimide compound solution having a solid content concentration of 65% by mass. The resulting modified maleimide compound had a weight average molecular weight (Mw) of approximately 2,700.

### Examples 1 and 2 and Comparative Examples 1 and 2

The components shown in Table 1 were stirred and mixed according to the blending composition shown in Table 1 together with 58 parts by mass of toluene and 10 parts by mass of methyl isobutyl ketone at room temperature, thereby preparing a thermosetting resin composition (varnish) having a solid content concentration of 60 to 65% by mass.

The vanish obtained above was coated on a glass cloth having a thickness of 0.08 mm (E Glass, available from Nitto Boseki Co., Ltd.), followed by drying with heat at 150° C. for 5 minutes, thereby producing a prepreg having a content of solid components derived from the thermosetting resin composition of approximately 47% by mass. A low profile copper foil (BF-ANP18, Rz of M surface: 1.5 μm, available from CIRCUIT FOIL Co., Ltd.) having a thickness of 18 μm was disposed on the upper and lower sides of the prepreg in such a manner that the M surface (matte surface) was in contact with the prepreg, followed by heat press molding under the conditions of a temperature of 230° C., a pressure of 3.0 MPa, and a time of 90 minutes, thereby producing a double-sided copper-clad laminate (thickness: 0.10 mm).

On one surface of the resulting double-sided copper-clad laminate, the copper foil was removed by etching while a part of the copper foil was allowed to remain, thereby producing a test piece having a part of the surface of the cured product of the thermosetting resin composition exposed (see FIG. 1). The test piece had a dimension of 540 mm in length×530 mm in width, and the copper foil remaining in the test piece had a dimension of 10 mm in length×530 mm in width.

The test piece obtained in each of the examples was subjected to the substrate visual inspection according to the following method.

### [Substrate Visual Inspection Method]

(1) The test piece was mounted on an automated optical inspection (AOI) device “Discovery-8000” (available from Orbotech Ltd.).
(2) Calibration was then performed. The entire test piece was imaged from above the test piece with the camera (i.e., the camera provided inside the AOI device). The image obtained through camera imaging was then converted to grayscale. After completing the conversion to grayscale, each one pixel (0.02 to 0.04 mm×0.02 to 0.04 mm), which was the minimum unit of the image, was assigned 256 levels and graphed. The graphs obtained in Examples 1 and 2 are shown in FIGS. 2 and 3, and the graphs obtained in Comparative Examples 1 and 2 are shown in FIGS. 4 and 5.

In FIGS. 2 and 3, the small peak on the right end is the peak derived from the metal foil, and the large peak on the left side is the peak derived from the cured product of the thermosetting resin composition. In Examples 1 and 2, the peak derived from the metal foil and the peak derived from the cured product of the thermosetting resin composition were separated off from each other in this manner. In Comparative Examples 1 and 2, on the other hand, an error occurred and failed to transfer to the subsequent operation. The result in Comparative Examples 1 and 2 is caused by the overlap of the peak derived from the metal foil and the peak derived from the cured product of the thermosetting resin composition as shown in FIGS. 4 and 5.
(3) In Examples 1 and 2, the threshold value between the peak derived from the metal foil and the peak derived from the cured product of the thermosetting resin composition was then set. The end point (right end) of the peak derived from the cured product of the thermosetting resin composition was designated as the minimum value, whereas the starting point (left end) of the peak derived from the metal foil was designated as the maximum value, from which the difference between the minimum value and the maximum value was set as the threshold value.

The calibration was thus completed.
(4) After the operation of the section (3) above, the visual inspection was performed by imaging the entire test piece from above the test piece with the camera (i.e., the camera provided inside the AOI device) again. In the imaging, the image size was ca. 3 mm×ca. 4 mm per one image, while not particularly limited.
(5) The inspection for the presence of defects was performed based on the image obtained in the section (4).

The substrate visual inspection using an AOI device was enabled in Examples 1 and 2 in the aforementioned manner.

TABLE 1

| | | | | | | Comparative | |
|---|---|---|---|---|---|---|---|
| | | | | Example | | Example | |
| | | | Unit | 1 | 2 | 1 | 2 |
| Blending | Thermosetting resin (A) | A-1 | part by mass | 23 | 15 | 23 | 15 |
| composition | | A-2 | | 3 | 2 | 3 | 2 |
| | High dielectric constant | B-1 | part by mass | 34 (15) | 64 (28) | 34 (15) | 64 (28) |
| | inorganic filler (B) | | (% by | | | | |
| | | | volume) | | | | |
| | Elastomer (C) | C-1 | part by mass | 5 | 3 | 5 | 3 |
| | Inorganic filler (D) | D-1 | part by mass | 27 (22) | 11 (9) | 27 (22) | 11 (9) |
| | | | (% by | | | | |
| | | | volume) | | | | |
| | Curing accelerator (E) | E-1 | part by mass *¹ | 0.5 | 0.5 | 0.5 | 0.5 |
| | | E-2 | | 0.5 | 0.5 | 0.5 | 0.5 |
| | | E-3 | | 0.78 | 0.78 | 0.78 | 0.78 |
| | Flame retardant (F) | F-1 | part by mass | 9 | 6 | 9 | 6 |
| | One or more kind selected | G-1 | part by mass | 0.17 | 0.17 | — | — |
| | from dye and pigment (G) | G-2 | | 0.43 | 0.43 | — | — |

*¹ Content per 100 parts by mass of resin components of thermosetting resin composition

The components described in Tables 1 are described below.

### [Thermosetting Resin (A)]

A-1: Modified maleimide compound obtained in Production Example 1
A-2: Polyphenylene ether having methacryloyl groups at both ends of molecule (weight average molecular weight: 1,700)

### [High Dielectric Constant Inorganic Filler (B)]

B-1: Strontium titanate, average particle diameter (d50): 1.6 μm

### [Elastomer (C): Styrene-Based Thermoplastic Elastomer]

C-1: Maleic anhydride-modified hydrogenated styrene-based thermoplastic elastomer (maleic anhydride-modified SEBS), acid number: 10 mgCH₃ONa/g, styrene content rate: 30%, MFR: 5.0 g/10 min (Measurement condition of MFR: measured under condition of 230° C. and a load of 2.16 kgf according to ISO 1133)

### [Inorganic Filler (D)]

D-1: Spherical fused silica: average particle diameter: 1.5 μm, 50% by mass slurry (solvent: toluene)

### [Curing Accelerator (E)]

E-1:2-Undecylimidazole
E-2: tri-n-Butylphosphine addition reaction product of p-benzoquinone
E-3: Dicyandiamide

### [Flame Retardant (F)]

F-1: Phosphate ester-based flame retardant having the following structural formula

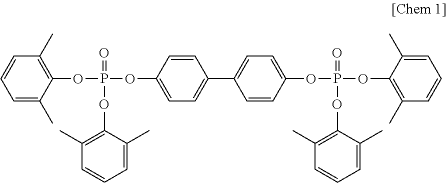 [SMILES: Cc1cccc(C)c1OP(=O)(Oc1ccc(-c2ccc(OP(=O)(Oc3c(C)cccc3C)Oc3c(C)cccc3C)cc2)cc1)Oc1c(C)cccc1C]

[One or More Kind Selected from Dye and Pigment (G)]
G-1: Yellow Dye “HR-50” (pyrazolone-based dye, available from Chuo synthetic Chemical Co., Ltd.)
G-2: Yellow Dye “HMT” (7-diethylamino-4-methylcoumarin, coumarin-based pigment, available from Tokyo Kasei Kogyo Co., Ltd.)

### REFERENCE SIGNS LIST

1: Remaining metal foil
2: Cured product of thermosetting resin composition

1. A thermosetting resin composition comprising:
a thermosetting resin (A); and
one or more kinds of a high dielectric constant inorganic filler (B) selected from the group consisting of a titanium-based inorganic filler and a zircon-based inorganic filler,
the thermosetting resin composition providing a chart obtained by performing a substrate visual inspection according to the following method, having a peak derived from a metal foil and a peak derived from a cured product of the thermosetting resin composition that are detected separately:
(substrate visual inspection method)
a metal-clad laminate including a cured product of the thermosetting resin composition and a metal foil laminated on each other is prepared, from which the metal foil is removed by etching while a part of the metal foil is allowed to remain, so as to produce a test piece having a part of a surface of the cured product of the thermosetting resin composition exposed, and the test piece is mounted on and inspected with an automated optical inspection device to provide a graph with a gray level as the abscissa and a pixel as the ordinate, in which a peak derived from the metal foil and a peak derived from the cured product of the thermosetting resin composition are detected.

2. The thermosetting resin composition according to claim 1, wherein the component (A) contains one or more kinds selected from the group consisting of an epoxy resin, a maleimide compound, a modified polyphenylene ether resin, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

3. The thermosetting resin composition according to claim 1, wherein the titanium-based inorganic filler is one or more kinds selected from the group consisting of titanium dioxide and a metal titanate.

4. The thermosetting resin composition according to claim 3, wherein the metal titanate is one or more kinds selected from the group consisting of an alkali metal titanate, an alkaline earth metal titanate, and lead titanate.

5. The thermosetting resin composition according to claim 1, wherein the zircon-based inorganic filler is an alkali metal zirconate.

6. The thermosetting resin composition according to claim 1, wherein the thermosetting resin composition further comprises one or more kinds selected from a dye and a pigment (G).

7. The thermosetting resin composition according to claim 1, wherein the peak derived from the metal foil appears at a gray level of 230 to 256, and the peak derived from the cured product of the thermosetting resin composition appears at a gray level of 220 or less.

8. A prepreg comprising the thermosetting resin composition according to claim 1 or a semi-cured product of the thermosetting resin composition.

9. A resin film comprising the thermosetting resin composition according to claim 1 or a semi-cured product of the thermosetting resin composition.

10. A metal-clad laminate comprising a cured product of the thermosetting resin composition according to claim 1 and a metal foil.

11. A metal-clad laminate comprising a cured product of a thermosetting resin composition and a metal foil,
the thermosetting resin composition containing:
a thermosetting resin (A); and
one or more kinds of a high dielectric constant inorganic filler (B) selected from the group consisting of a titanium-based inorganic filler and a zircon-based inorganic filler,
the metal-clad laminate providing a chart obtained by performing a substrate visual inspection according to the following method, having a peak derived from the metal foil and a peak derived from the cured product of the thermosetting resin composition that are detected separately:
(substrate visual inspection method)
the metal foil is removed by etching from the metal-clad laminate while a part of the metal foil is allowed to remain, so as to produce a test piece having a part of a surface of the cured product of the thermosetting resin composition exposed, and the test piece is mounted on and inspected with an automated optical inspection device to provide a graph with a gray level as the abscissa and a pixel as the ordinate, in which a peak derived from the metal foil and a peak derived from the cured product of the thermosetting resin composition are detected.

12. The metal-clad laminate according to claim 11, wherein the titanium-based inorganic filler is one or more kinds selected from the group consisting of titanium dioxide and a metal titanate.

13. The metal-clad laminate according to claim 12, wherein the metal titanate is one or more kinds selected from the group consisting of an alkali metal titanate, an alkaline earth metal titanate, and lead titanate.

14. The metal-clad laminate according to claim 11, wherein the zircon-based inorganic filler is an alkali metal zirconate.

15. The metal-clad laminate according to claim 11, wherein the metal-clad laminate further comprises one or more kinds selected from a dye and a pigment (G).

16. The metal-clad laminate according to claim 11, wherein the peak derived from the metal foil appears at a gray level of 230 to 256, and the peak derived from the cured product of the thermosetting resin composition appears at a gray level of 220 or less.

17. A printed wiring board comprising a cured product of the thermosetting resin composition according to claim 1.

18. An antenna device comprising the metal-clad laminate according to claim 10.

19. An antenna module comprising a feeding circuit and the antenna device according to claim 18.

20. A communication device comprising a baseband signal processing circuit and the antenna module according to claim 19.
